(19) United States
(12) Patent Application Publication
(10) Pub. No.: US 2012/0161170 A1
(43) Pub. Date: Jun. 28, 2012

(54) GENERATION OF RADIATION CONDUCIVE TO PLANT GROWTH USING A COMBINATION OF LEDS AND PHOSPHORS

(75) Inventors: Eden Dubuc, Lachine (CA); Anirudha R. Deshpande, Cleveland Heights, OH (US)

(73) Assignee: GE Lighting Solutions, LLC

(21) Appl. No.: 12/978,930

(22) Filed: Dec. 27, 2010

(51) Int. Cl. H01L 33/44; H01L 33/50

(52) U.S. Cl. 257/89; 257/98; 257/E33.068; 257/E33.061

(57) ABSTRACT

In accordance with one aspect of the present disclosure, a light emitting device for producing radiation optimal for plant growth is provided. The light emitting device comprises at least one LED chip having a peak wavelength disposed on a support, a phosphor material radiationally coupled to the at least one LED chip. The phosphor materials are capable of absorbing at least a portion of the radiation from the at least one LED chip and emitting light of a second wavelength. The light emitting device further includes an optical element at least partially covering the at least one LED chip and support. The light emitting device is capable of uniformly mixing the red and blue radiation to produce pink radiation.

### BACKGROUND

The present exemplary embodiments relate generally to lighting assemblies. They find particular application in conjunction with maximizing plant growth using artificial lighting devices, and will be described with particular reference thereto. However, it is to be appreciated that the present exemplary embodiments are also amenable to other like applications.

Photosynthesis is the process whereby plants convert energy from sunlight or another light source to chemical focus of energy that can be used by biological systems. Energy for photosynthesis is provided by light that is absorbed by the pigments of the plant. The various colors and intensities of light are used differently according to particular photosynthesis reactions. Blue light plus water plus carbon dioxide produces oxygen and sugar, while red light plus water plus sugar produces plant cells. Photosynthetically active radiation, often abbreviated PAR, designates the spectral range (wave band) of solar radiation from 400 to 700 nanometers that photosynthetic organisms are able to use in the process of photosynthesis. This spectral region corresponds more or less with the range of light visible to the human eye. However, unlike the human eye that has a peak sensitivity in the yellow-green region (around 550 nm), plants respond most efficiently to red and blue light, the peaks being around 435, 455, 660 and 680 nm. Although blue light provides the most efficient food for plants, a plant illuminated with only blue light will fail to develop bulk due to suffocation and unbalanced morphological development. Red light promotes height and blue light promotes growth in girth. Accordingly, a combination of blue and red light, producing a mauve or pink radiation, is a basic necessity for plant growth.

In recent years, it has become increasingly cost-effective to use artificial lights for assisting plant growth in regions close to the earth's poles. Lighting costs and lamps have become less expensive, and very efficient light sources are now available in high wattages. These developments along with the ability to preserve and transport plants and produce as well as special new products in demand today have led to the increased use of artificial light for plant growth. Artificial light can be used for plant growth in three different ways: 1) to provide all the light a plant needs to grow; 2) to supplement sunlight, especially in winter months when daylight hours are short and the spectral content is different; and 3) to increase the length of the “day” in order to trigger specific growth and flowering.

One common type of artificial lighting used for plant growth includes high intensity discharge (HID) lights, implementing either metal halide bulbs or high pressure sodium bulbs. Metal halide bulbs produce an abundance of light in the blue spectrum include an average lifespan of about 10,000 hours. High pressure sodium bulbs emit an orange-red radiation that triggers hot in plants to increase flowering and budding, but are deficient in the blue spectrum. The average life span of a high pressure sodium bulb is about 18,000 hours. Another common light source used in artificial plant grown includes fluorescent lights. Fluorescent lights produce light in a variety of spectrums, depending on the type of bulb. For instance, warm white bulbs give off more red light, while cool white bulbs give off more blue light. Therefore, different bulbs must be used for different growth periods. Florescent lights have a life span of about 20,000 hours. However, according to current plant growth lighting applications, it is not possible to precisely tailor spectra to be in tune with plant needs. Accordingly, there remains a need to provide a method of improving a light spectra's accuracy when generating a mauve or pink light.

Moreover, traditional artificial light sources often produce light at wavelengths not ideal for the workers that tend to the plants, which can often lead to problems, such as headaches and eye strain. Accordingly, white light producing LEDs have been introduced that emit light in every color of the spectrum, including blue and red, and may be tailored to maximize plant growth, while still providing comfortable lighting for workers working around plants. However, there remains a need for a white light produced by a specially tailored combination of radiation to maximize plant growth, while still providing comfortable lighting for workers working around plants.

### BRIEF SUMMARY

In accordance with one aspect of the present disclosure, a light emitting device for producing radiation optimized for plant growth is provided. The light emitting device comprises at least one LED chip having a peak wavelength disposed on a support, a phosphor material radiationally coupled to the at least one LED chip. The phosphor materials are capable of absorbing at least a portion of the radiation from the at least one LED chip and emitting light of a second wavelength. The light emitting device further includes an optical element at least partially covering the at least one LED chip and support. The light emitting device is capable of uniformly mixing the red and blue radiation to produce pink radiation.

In accordance with another aspect of the present disclosure, a light emitting device for producing radiation customized for plant growth. The light emitting device comprises at least one of a blue and near UV emitting LED chip having a peak wavelength of between 400 nm-490 nm disposed on a support, at least one red emitting LED chip having a peak wavelength of between 600 nm-700 nm disposed on the support, and an optical element at least partially covering the at least one LED chip and support. The light emitting device is capable of uniformly mixing the red and blue radiation to produce pink radiation.

In accordance with yet another aspect of the present disclosure, a white light emitting device producing radiation customized for plant growth. The white light emitting device includes at least one of a blue and near UV LED chip having a peak wavelength from 400 nm-490 nm disposed on a support, and a phosphor material comprising a blend of one or more of blue, green, yellow, and red phosphors radiationally coupled to one or more of said at least one LED chip. The phosphor materials are capable of absorbing at least a portion of the radiation from the at least one LED chip and emitting light of a second wavelength. The white light emitting device further includes an optical element at least partially covering the at least one LED chip and support. The white light emitting device is capable of uniformly mixing the various radiations.

### BRIEF DESCRIPTION OF THE DRAWINGS

The invention may take form in various components and arrangements of components, and in various process operations and arrangements of process operations. The drawings are only for purposes of illustrating embodiments and are not to be construed as limiting the invention.

FIGS. 1(a) and (b) illustrate a pink light emitting device according to one aspect of the present disclosure;

FIG. 2 illustrates a pink light emitting device according to another aspect of the present disclosure;

FIGS. 3(a) and (b) illustrate a pink light emitting device according to another aspect of the present disclosure;

FIGS. 4(a) and (b) illustrate a pink light emitting device according to another yet another aspect of the present disclosure;

FIGS. 5(a) and (b) illustrate a white light emitting device according to one aspect of the present disclosure;

FIG. 6 illustrates a white light emitting device according to another aspect of the present disclosure; and

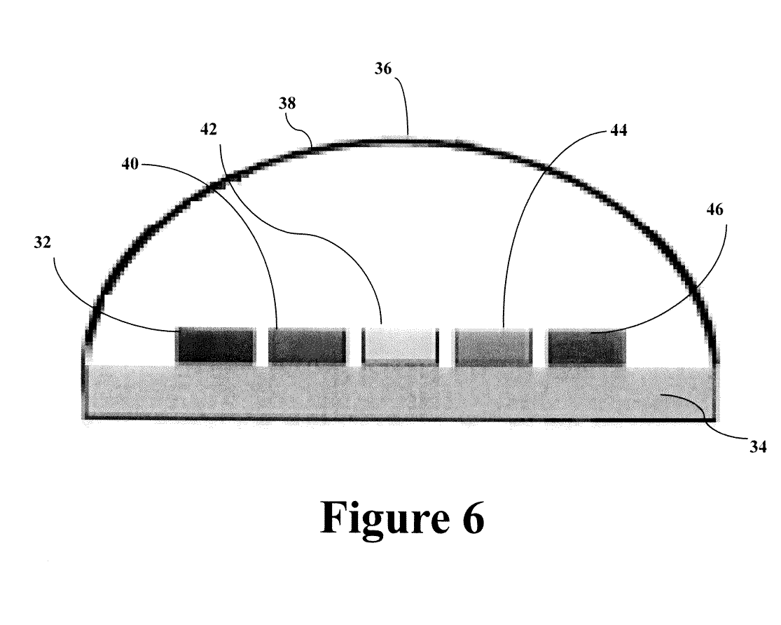

FIG. 7 is a graphical illustration of different current light source spectrum; and

FIG. 8 is a graphical illustration of the spectral distribution of three different variations of white LEDs and a pink LED spectrum having the same radiant power.

### DETAILED DESCRIPTION OF PREFERRED EMBODIMENT

Techniques have been developed for converting the light emitted from LEDs to useful light for a variety of purposes. According to one technique, the LED is coated or covered with a phosphor layer. A phosphor is a luminescent material that absorbs radiation energy in a portion of the electromagnetic spectrum and emits energy in another portion of the electromagnetic spectrum. Phosphors of one important class are crystalline inorganic compounds of very high chemical purity and of controlled composition to which small quantities of other elements (called “activators”) have been added to convert them into efficient fluorescent materials. With the right combination of activators and host inorganic compounds, the color of the LED's emission can be controlled. Most useful and well-known phosphors emit radiation in the visible portion of the electromagnetic spectrum in response to excitation by electromagnetic radiation outside the visible range.

The color of the visible light generated by the device is dependent on the identity and amounts of the particular components of the phosphor materials used as well as the amount of current supplied to any of the given sub arrays. As used herein, the terms “phosphor material” and “luminescent material” The phosphor material in each sub array may include only a single phosphor composition or two or more phosphors of basic color, for example a particular mix with one or more of a green, blue and red phosphor to emit a desired color of light are used interchangeably and may be used to denote both a single phosphor composition as well as a blend of two or more phosphors. As used herein, the term “sub array” is used to denote one or more chips and a radiationally coupled phosphor material. “Radiationally coupled” means that the one or more chips and the phosphor material are associated with each other so that at least part of the radiation emitted from one is transmitted to the other.

Generally, an LED may contain at least one semiconductor layer comprising GaN, MN or SiC. For example, the LED may comprise a nitride compound semiconductor represented by the formula InᵢGaⱼAlₖN (where 0≦i; 0≦j; 0≦k and i+j+k=1) having a peak emission wavelength greater than about 200 nm and less than about 500 nm. Such LED semiconductors are known in the art. The radiation source is described herein as an LED for convenience. However, as used herein, the terms “LED” and “LED chip” are meant to encompass all semiconductor radiation sources including, e.g., semiconductor laser diodes. The LEDs can be packaged LEDs or chips on a printed circuit board (“PCB”), as is known in the art.

Conventional light sources comprise one or more semiconductor light sources, such as a light emitting diode (LED) chips or laser diodes and are positioned on a PCB or other support. Although the light emitting devices illustrated in the figures provided herein display five LEDs positioned on the same support, such is not intended to be limiting, and it is to be appreciated that a light emitting device may include any number of LED chips as desired by a user.

Light that is emitted by the light sources impinges on different phosphor materials associated with each individual light source, which convert all or a portion of the emitted light from the light sources to longer wavelengths, preferably in the visible range. The phosphor material may be deposited directly on the LED chip by any appropriate method. The phosphor material utilized can vary, depending upon the desired color of secondary light that will be generated by the light emitting device. A single LED may associate with each phosphor material or alternatively there can be any number of LEDs associated with each phosphor material. Each LED/associated phosphor material may be thought of as a sub-array. As noted, there can be more than one LED in each sub-array.

The phosphor materials may alternatively or additionally be disposed on the inside surface, outside surface, or interspersed within a light transmissive shell or lens disposed over the LED light source and at least a portion of the support (i.e. printed circuit board). The shell can take any form, such as hemispherical in shape. Of course other shapes are also possible depending on the desired use of the light emitting devices. Associating the phosphor material with the light transmissive shell creates a remote phosphor configuration with the phosphor material spaced apart from the light source. This space between the shell and the light source can be an air gap or filled with a type of gas or other encapsulant material. The light transmissive shell or lens on or in which the phosphor material is contained may be, for example, glass or plastic. The encapsulant material may comprise an epoxy, plastic, low temperature glass, polymer, thermoplastic, thermoset material, resin, or other type of LED encapsulating material known in the art. Preferably, both the shell and the encapsulant (if present) are transparent or substantially optically transmissive with respect to the wavelength of light produced by the LED chip and a phosphor composition. In addition, the encapsulant material may comprise a diffusing feature that is capable of mixing colored radiation.

The present disclosure is directed to light emitting diodes (LEDs) for use in plant growth lighting applications. LEDs are more efficient as artificial light sources than the existing HID or fluorescent light source applications and can provide precise wavelength tailoring to tune into a plant's specific growth needs. It is to be appreciated that various combinations of phosphors and LED chips may be used to produce radiation that is conducive to plant growth. Such light emitting devices may include a combination of blue and red radiation generated by combinations of phosphors and LED chips. While not intended to be limiting, suitable phosphor materials for use with the present aspect of the disclosure include:

Blue:
Sr₅(PO₄)₃Cl:Eu²⁺
(Ba,Sr,Ca)₅(PO₄)₃(Cl,F,Br,OH):Eu²⁺,Mn²⁺,Sb³⁺
(Ba,Sr,Ca)MgAl₁₀O₁₇:Eu²⁺,Mn²⁺
(Ba,Sr,Ca)BPO₅:Eu²⁺,Mn²⁺
(Sr,Ca)₁₀(PO₄)₆*nB₂O₃:Eu²⁺
2SrO*0.84P₂O₅*0.16B₂O₃:Eu²⁺
Sr₂Si₃O_{8*2}SrCl₂:Eu²⁺,Mn²⁺
Ba₃MgSi₂O₈:Eu²⁺
Sr₄Al₁₄O₂₅:Eu²⁺ (SAE)
BaAl₈O₁₃:Eu²⁺

Red:
(Gd,Y,Lu,La)₂O₃:Eu³⁺,Bi³⁺
(Gd,Y,Lu,La)₂O₂S:Eu³⁺,Bi³⁺
(Gd,Y,Lu,La)VO₄:Eu³⁺,Bi³⁺
(Ca,Sr)S:Eu²⁺
SrY₂S₄:Eu²⁺
CaLa₂S₄:Ce³⁺
(Ca,Sr)S:Eu²⁺
3.5MgO*0.5MgF₂*GeO₂:Mn⁴⁺
(Ba,Sr,Ca)MgP₂O₇:Eu²±,Mn²⁺
(Y,Lu)₂WO₆:Eu³⁺,Mo⁶⁺
(Ba,Sr,Ca)ₓSi_{y}N_{z}:Eu²⁺
K₂SiF₆:Mn⁴⁺
K₂TiF₆:Mn⁴⁺

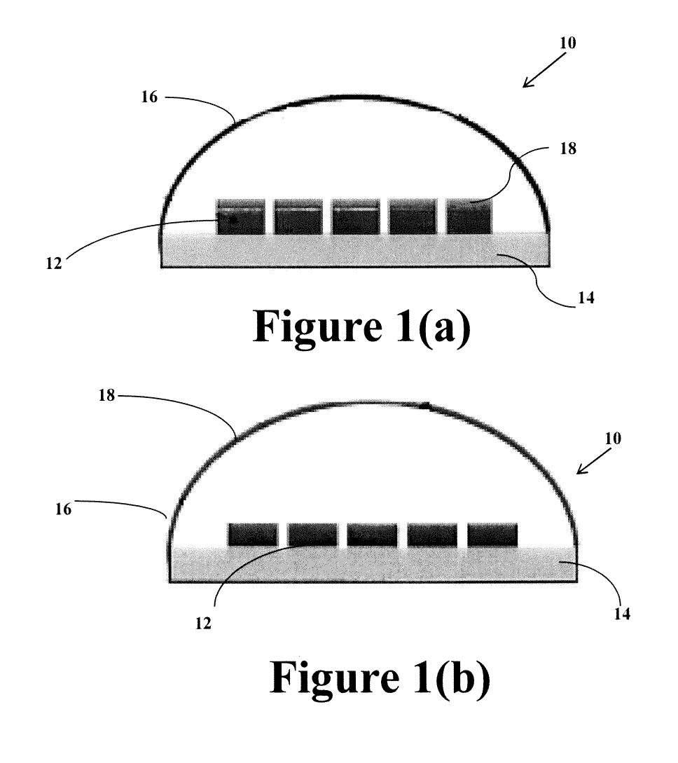

According to one exemplary embodiment illustrated in FIG. 1(a),(b), a light emitting device 10 is provided having blue or near UV emitting LED chips 12 (emitting between 400 nm-490 nm) provided on a support 14, such as a PCB. The blue or near-UV chips 12 emit radiation at a wavelength of about 420 nm-480 nm. As best illustrated in FIG. 1(a), the blue or near-UV LED chips 12 are radiationally coupled to a red emitting phosphor material 18 (600 nm-700 nm) applied as a conformal coating or on the top of the chip. When using near-UV emitting LED chips 12 the red emitting phosphor 18 preferably comprises Mn activated magnesium fluoro germanate (3.5 MgO.0.5 MgF₂.GeO₂:Mn⁴+). When the LED chips 12 included in the light emitting device 10 are blue, the red emitting phosphor material 18 may comprise at least one of Mn activated Potassium Fluoro Titanate (K₂TiF₆:Mn⁴⁺) or Potassium Fluoro Silicate (K₂SiF₆:Mn⁴⁺). Alternatively, or in addition to, a broad red emitting phosphor may be used such as calcium, barium, or calcium+barium silicon oxynitride and/or nitride activated by Eu, and/or sensitized by Ce plus activated by Eu. The light emitting device further includes a light transmissive shell 16, which preferably comprises an optical element, enabling uniform mixing of red and blue radiations to generate a mauve or pink light precisely tailored for plant growth.

Alternatively, or in addition to, the red phosphor material 18 is provided in a remote phosphor configuration, such that the red phosphor material 18 is coated on the either the outside or inside surface, or interspersed within the light transmissive shell 16, as best illustrated in FIG. 1(b). It is further contemplated herein that the light emitting device 10 may comprise a combination of coated phosphor material on the surface of a light source and interspersed phosphor material on or within the shell 16.

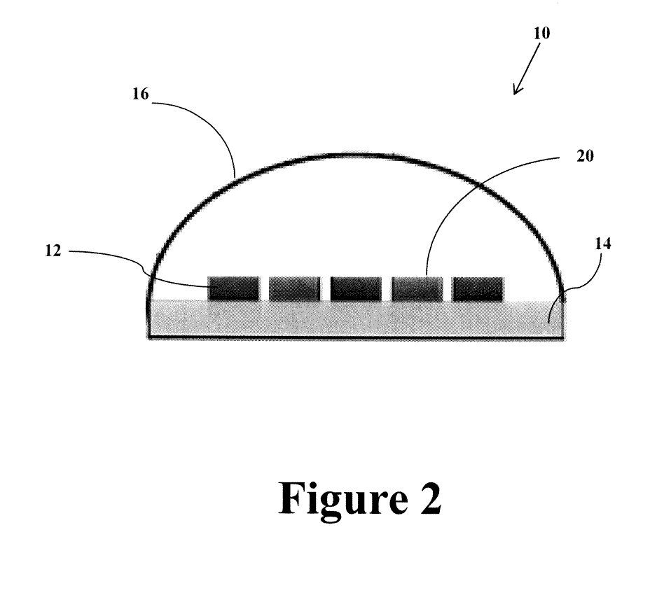

In another embodiment illustrated in FIG. 2, a light emitting device 10 is provided, similar to that described above with reference to FIG. 1; however, rather than combining blue or near-UV LED emitted radiation with red radiation generated by a phosphor excited by the LED chips 12, red emitting LED chips 20 (600 nm-700 nm) are provided and interspersed with the blue or near-UV LED chips 12. The light emitting device 10 according to this exemplary embodiment may include any number of red 20 and blue or near UV LED chips 12, although there should be at least one red emitting LED chip and at least one blue or near UV emitting chip. The light transmissive shell 16 enables uniform mixing of the red and blue radiation to produce a mauve or pink light conducive for optimal plant growth.

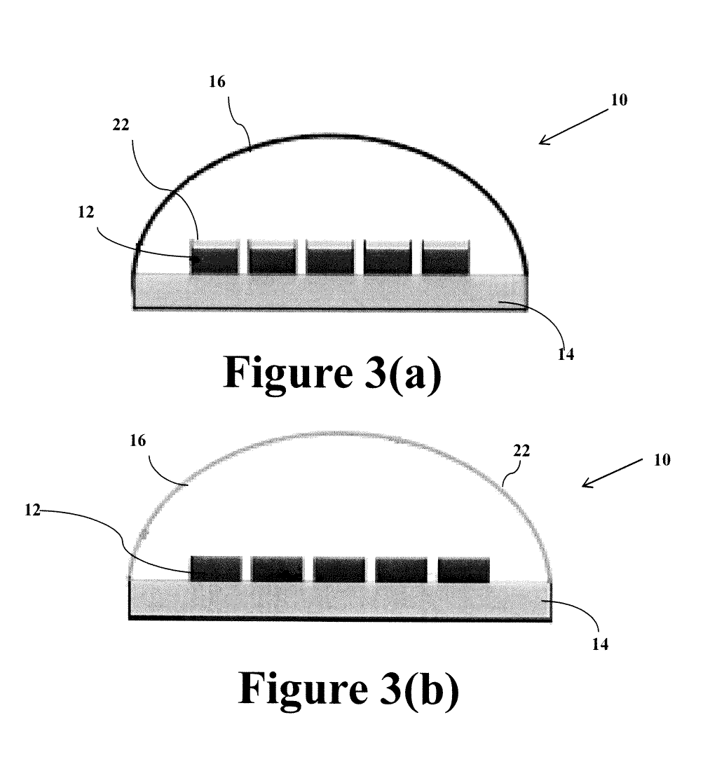

In accordance with yet another embodiment, a light emitting device 10 is provided, as best illustrated in FIG. 3(a),(b) that includes blue or near UV emitting LED chips 12 (emitting radiation between 400 nm-490 nm) disposed on a support 14. A blend of blue and red emitting phosphor material 22 is provided, as a conformal coating over the LED chips 12 (FIG. 3(a)), and/or in a remote phosphor configuration, such that the phosphor blend 22 is disposed at least one of the outside surface, inside surface, and/or interspersed within the light transmissive shell 16. The blue phosphor material preferably comprises Eu excited Strontium Chlorapatite (Sr₅(PO₄)₃Cl:Eu²⁺) when the LED chips are near UV. When the LED chips are themselves blue, the blue LED itself may act as the blue radiation source. As with the embodiments above, the optical element enables uniform mixing of red and blue radiation to generate a mauve or pink light conducive for plant growth.

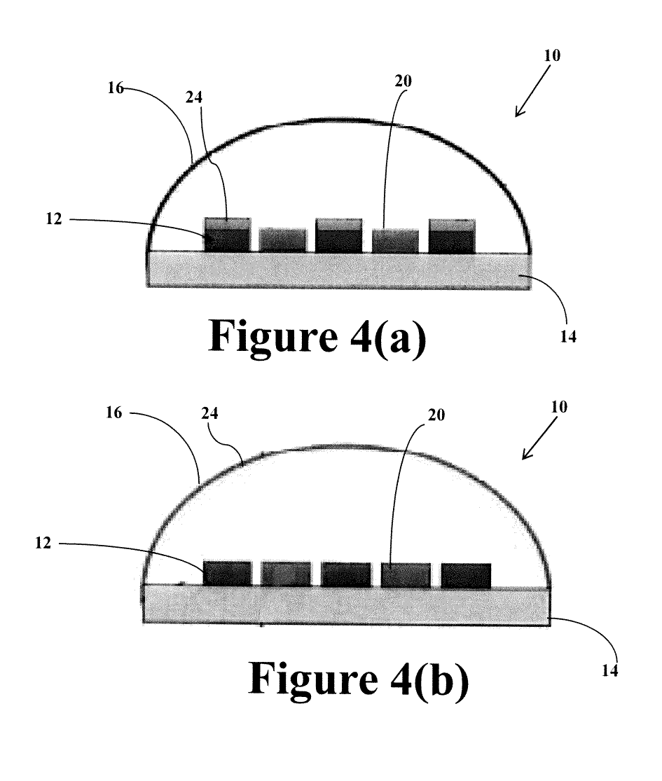

FIG. 4(a),(b) illustrates another embodiment of the present disclosure that includes a light emitting device 10 similar to those described above that includes a mixture of blue or near UV emitting LED chips 12 emitting radiation between 400 nm and 490 nm and red emitting LED chips 20 emitting between 600 nm and 700 nm. According to the illustrative embodiment of FIG. 4(a), The blue or near UV emitting LED chips 12 are coated with a blue emitting phosphor 24, such as Sr₅(PO₄)₃Cl:Eu²⁺, emitting blue radiation between 420 and 480 nm. According to the illustrative embodiment of FIG. 4(b), alternatively, or in addition to coating the blue or near UV emitting LED chips 12 with the blue emitting phosphor material 24, the blue emitting phosphor material 24 is coated on the inside surface, outside surface or interspersed within the light transmissive shell 16. In both configurations, the shell then uniformly mixes the red and blue radiations to generate mauve or pink light precisely tailored for plant growth.

The embodiments provided above illustratively depict various combinations of LED chips and phosphors for producing a pink light emitting device with radiation conducive for plant growth. In each of the examples, the blue component may contribute anywhere from 1-99% of the spectral weight, while the balance would be the red component. Although it is known that the blue component helps with the health of the plant and the red component helps with the plant's ability to bear fruits and flowers, the present disclosure provides the ability to tailor the generation of each color by changing the blue and red spectral weights. The ideal spectral weight may change depending on the type of plant, the effect desired on the plant, the compensation desired to produce with a particular light source, and the like.

In addition to colored LEDs, a combination of LED generated light and phosphor generated light may be used to produce white light that is still optimal for plant growth. Common white LEDs are based on blue emitting GaInN chips. The blue emitting chips are coated with a phosphor that converts some of the blue radiation to a complementary color, e.g. a yellow-green emission. The total of the light from the phosphor and the LED chip provides a color point with corresponding color coordinates (e.g. x and y on the 1931 CIE chromaticity diagram) and correlated color temperature (CCT) and vertical distance from the blackbody locus (dbb). Any given set of a CCT and a dbb value (wherein the latter can be positive, negative or zero) corresponds to a single set of an x and a y value, and such sets can be used interchangeably. However, CCT and dbb are defined only in the vicinity of the blackbody (a.k.a. Planckian) locus, whereas x and y cover the entire color space. In white lamps of any CCT, the color point preferably lies substantially on the Planckian locus, and the absolute dbb value is preferably less than 0.010, more preferably less than 0.005, on either side of the Planckian locus in the 1931 CIE diagram.

In accordance with another aspect of the present disclosure, a light emitting device is provided that produces white light. The particular phosphors contemplated with the LED lamps may include a variety of phosphors such as green, blue, orange, or other color phosphors that may be used to customize the mauve or pink color of the resulting light provided herein. While not intended to be limiting, suitable phosphor for use with the present aspect of the disclosure include:

Blue-Green:
Sr₄Al₁₄O₂₅:Eu²⁺
BaAl₈O₁₃:Eu²⁺
2SrO-0.84P₂O_{5-0.16}B₂O₃:Eu²⁺
(Ba,Sr,Ca)MgAl₁₀O₁₇:Eu²⁺,Mn²⁺
(Ba,Sr,Ca)₅(PO₄)₃(Cl,F,OH):Eu²⁺,Mn²⁺,Sb³⁺

Green:
(Ba,Sr,Ca)MgAl₁₀O₁₇:Eu²⁺,Mn²⁺ (BAMn)
(Ba,Sr,Ca)Al₂O₄:Eu²⁺
(Y,Gd,Lu,Sc,La)BO₃:Ce³⁺,Tb³⁺
Ca₈Mg(SiO₄)₄Cl₂:Eu²⁺,Mn²⁺
(Ba,Sr,Ca)₂(Mg,Zn)Si₂O₇:Eu²⁺
(Sr,Ca,Ba)(Al,Ga,In)₂S₄:Eu²⁺
(Y,Gd,Tb,La,Sm,Pr,Lu)₃(Al,Ga)₅O₁₂:Ce³
Mg,Zn)(SiO₄)₄Cl₂:Eu²⁺,Mn²⁺ (CAST)
Na₂Gd₂B₂O₇:Ce³⁺,Tb³⁺
(Ba,Sr)₂(Ca,Mg,Zn)B₂O₆:K,Ce,Tb

Yellow-Orange:
(Sr,Ca,Ba,Mg,Zn)₂P₂O₇:Eu²⁺,Mn²⁺ (SPP);
(Ca,Sr,Ba,Mg)₁₀(PO₄)₆(F,Cl,Br,OH):Eu²⁺,Mn²⁺ (HALO);

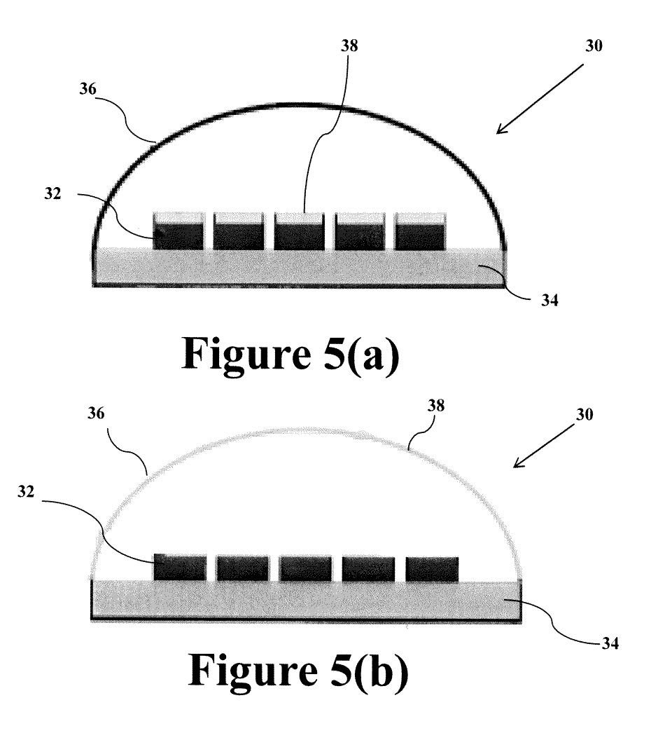

FIG. 5(a) illustratively depicts one embodiment of this aspect, wherein the white light emitting device 30 includes one or more blue or near-UV emitting LED chips 32 emitting radiation between 400 nm and 490 nm disposed on a support 34. A blend of blue, green, yellow, and/or red emitting phosphors 38 are disposed on, and excited by, the LED chips 32. Alternatively, or in addition to, the blend of phosphors 38 may be disposed on the inside surface, outside surface, or interspersed within the light transmissive shell 36 as depicted in FIG. 5(b). When using near UV LED chips the red emitting phosphor preferably comprises Mn activated magnesium fluoro germanate (3.5 MgO.0.5 MgF₂.GeO₂:Mn⁴+). When the LED chips implemented are blue, the red emitting phosphor may comprise at least one of Mn activated Potassium Fluoro Titanate (K₂TiF₆:Mn⁴⁺) or Potassium Fluoro Silicate (K₂SiF₆:Mn⁴⁺). Alternatively, or additionally, a broad red emitting phosphor may be used such as calcium, barium, or calcium+barium silicon oxynitride and/or nitride activated by Eu, and/or sensitized by Ce plus activated by Eu. The blue phosphor preferably comprises Eu excited Strontium Chlorapatite (Sr₅(PO₄)₃Cl:Eu²⁺) when the LED chips are near UV. When the LED chips 32 are themselves blue, the blue LED itself may act as the blue radiation source.

It is further contemplated herein that LED chips emitting a variety of colors, including blue (400-490 nm) 32, near UV, green (500-570 nm) 40, yellow 42, orange 44, and/or red (600-700 nm) 46 are all disposed on a support 34 of a white light emitting device 30. A blend of phosphors 38 emitting various color radiation may be disposed on the inside surface, outside surface, or interspersed within the light transmissive shell 36, which is configured to uniformly mix the various colors to generate white light. The blend of phosphors is preferably combined with complementary radiation from the various LED chips. According to this structure, at least one blue emitting LED and at least one red LED is required to be present in the light emitting device.

In either structure, the optical element of the light transmissive shell 36 is capable of uniformly mixing the various radiations to emit white light. Preferably, the spectral weight of the red and blue components is at least 50%, while the remaining components provide less than 50%. The white light generated preferably achieves a CCT value of about 2,500K to 10,000K, although the color point of these blends will not necessarily be on the black body locus. Therefore, the light emitting device will include specifically tailored amounts of blue and red radiation, while emitting white light that is suitable for workers.

Each phosphor material can include one or more individual phosphor compositions. The specific amounts of the individual phosphor compositions used in the phosphor materials will depend upon the desired color temperature for each phosphor material. The relative amounts of each phosphor in the phosphor materials can be described in terms of spectral weight. The spectral weight is the relative amount that each phosphor composition contributes to the overall emission spectrum of the phosphor material. Additionally, part of the LED light may be allowed to bleed through and contribute to the light spectrum of the device if necessary. The amount of LED bleed can be adjusted by changing the optical density of the phosphor layer, as routinely done for industrial blue chip based white LEDs. Alternatively, it may be adjusted by using a suitable filter or a pigment.

The spectral weight amounts of all the individual phosphors in each phosphor material should add up to 1 (i.e. 100%) of the emission spectrum of the individual phosphor material. Likewise, the spectral weight amounts of all of the phosphor materials and any residual bleed from the LED source should add up to 100% of the emission spectrum of the light emitting device.

The ratio of each of the individual phosphors in the phosphor blend may vary depending on the characteristics of the desired light output. The relative proportions of the individual phosphors in the various embodiment phosphor blends may be adjusted such that when their emissions are blended and employed in an LED lighting device, there is produced visible light of predetermined ccx and ccy values on the CIE chromaticity diagram.

The light emitting device described herein provides various advantages over both HID and fluorescent lighting applications used for plant growth in addition to the specific color tailoring provided above. As opposed to HID lights with life spans of about 10,000 hours, and fluorescent lights with life spans of about 20,000 hours, LEDs include life spans of over 50,000 hours and continue to improve. Moreover, LED lighting applications for plant growth are much more efficient than the existing HID or fluorescent applications, such that increased savings are possible by LED implementation. However, it is contemplated herein to use the LED devices provided herein in conjunction with fluorescent lamps, wherein the fluorescent lamps provide white light suitable for workers and LEDs are targeted on plants to help plant growth.

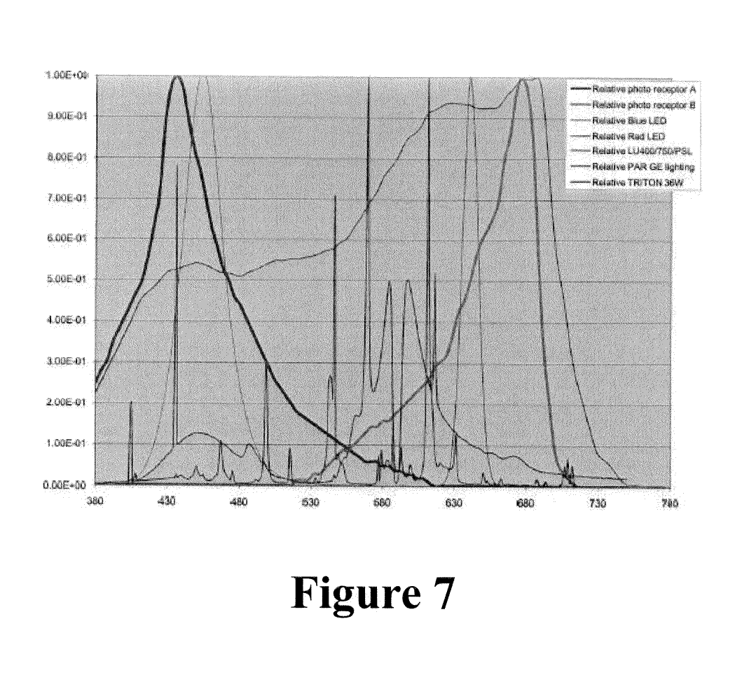

FIG. 7 graphically illustrates different light sources and hypothesized photosynthesis spectral distribution curves. The graph projects that the photosynthesis absorption curves for the LEDs are better than those for HID and fluorescent tube at targeting to the peak efficiency.

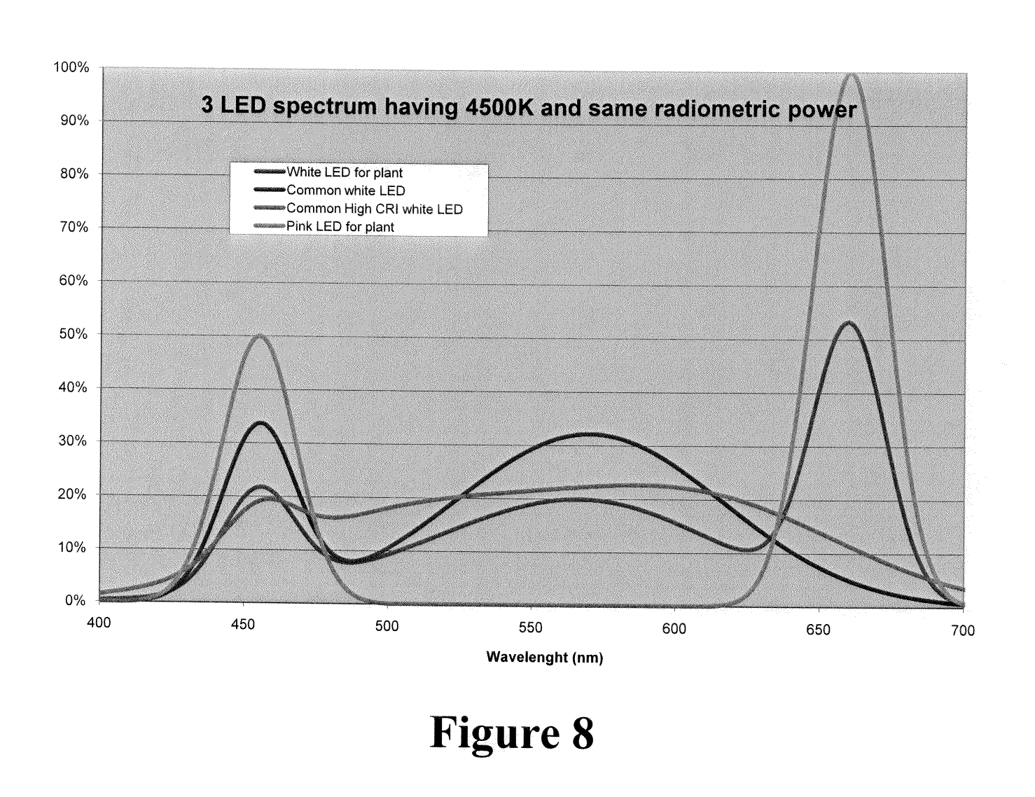

The spectral distribution of white LEDs can be modified without changing the color appearance. FIG. 8 illustrates three different types of white LED emitting 4100 k (white LED for plants, common white LED, and common high CRI white LED) and one pink LED. All four curves have the same radiant power. If the photosynthesis blue range is defined as being from about 410 nm to 490 nm and the photosynthesis red range as being from 610 nm to 700 nm, there is only about 40% of the common white LED radiant power used by the photosynthesis of the plant. Implementing a high CRI white LED, this ratio increases to about 45%, and optimizing the spectral distribution for plants this ratio can go up to about 60%, as reflected in the spectral curves of FIG. 8.

Modifications, alterations, and combinations will occur to others upon reading and understanding the preceding detailed description. It is intended that the invention be construed as including all such modifications and alterations insofar as they come within the scope of the appended claims or the equivalents thereof.

What is claimed is:

1. A light emitting device for producing radiation optimized for plant growth comprising:
at least one LED chip having a peak wavelength and being disposed on a support;
a phosphor material radiationally coupled to the at least one LED chip, said phosphor material being capable of absorbing at least a portion of the radiation from the at least one LED chip and emitting light of a second wavelength; and
an optical element at least partially covering the at least one LED chip and support, wherein said light emitting device is configured to produce pink radiation.

2. The light emitting device according to claim 1, wherein the at least one LED chip includes one or more of blue and near-UV LED chips.

3. The light emitting device according to claim 1, wherein said optical element is configured to uniformly mix the red and blue radiation to produce said pink radiation.

4. The light emitting device according to claim 1, wherein said phosphor material includes a red emitting phosphor material.

5. The light emitting device according to claim 4, wherein said at least one LED chip includes near-UV LED chips and said red phosphor material comprises 3.5 MgO.0.5 MgF₂.GeO₂:Mn⁴⁺.

6. The light emitting device according to claim 4, wherein said at least one LED chip includes blue LED chips and said red phosphor material comprises at least one of K₂TiF₆:Mn⁴⁺ and K₂SiF₆:Mn⁴⁺.

7. The light emitting device according to claim 4, wherein said red emitting phosphor material is one of a conformal coating and disposed on top of said at least one LED chips.

8. The light emitting device according to claim 4, wherein said red emitting phosphor material is at least one of coated on the top surface, the bottom surface, and interspersed within said optical element.

9. The light emitting device according to claim 1, wherein said phosphor material comprises a blend of blue and red emitting phosphors.

10. The light emitting device according to claim 9, wherein said blended phosphor material is one of a conformal coating and disposed on top of said at least one LED chips.

11. The light emitting device according to claim 9, wherein said blended phosphor material is at least one of coated on the top surface, the bottom surface, and interspersed within said optical element.

12. The light emitting device according to claim 1, wherein said at least one LED chip includes at least one red and one blue emitting LED chip.

13. The light emitting device according to claim 12, wherein said phosphor material comprises a blue emitting phosphor.

14. The light emitting device according to claim 13, wherein said phosphor material is at least one of disposed on said at least one blue emitting LED chip, coated on the top surface, the bottom surface, and interspersed within said optical element.

15. A light emitting device for producing radiation optimal for plant growth comprising:
at least one of a blue and near-UV emitting LED chip having a peak wavelength of between 400 nm-490 nm disposed on a support;
at least one red emitting LED chip having a peak wavelength of between 600 nm-700 nm disposed on the support; and
an optical element at least partially covering the at least one LED chip and support, wherein said light emitting device is configured to produce pink radiation.

16. A white light emitting device producing radiation customized for plant growth comprising:
at least one of a blue and near-UV LED chip having a peak wavelength from 400 nm-490 nm disposed on a support;
a phosphor material comprising a blend of one or more of blue, green, yellow, and red phosphors radiationally coupled to said at least one LED chip, said phosphor materials being capable of absorbing at least a portion of the radiation from the at least one LED chip and emitting light of a second wavelength; and
an optical element at least partially covering the at least one LED chip and support.

17. The white light emitting device according to claim 16, wherein said optical element is capable of uniformly mixing various radiations into white light.

18. The white light emitting device according to claim 16, further including one or more of a green, red, orange, and yellow emitting LED chips.

19. The white light emitting device according to claim 16, wherein said at least one LED chips include near-UV LED chips and said red phosphor material comprises 3.5 MgO.0.5 MgF₂.GeO₂:Mn⁴+.

20. The white light emitting device according to claim 16, wherein said at least one LED chips include blue LED chips and said red phosphor material comprises at least one of K₂TiF₆:Mn⁴⁺ and K₂SiF₆:Mn⁴⁺.

21. The white light emitting device according to claim 16, wherein said at least one LED chip includes near-UV LED chips and said blue phosphor comprises Sr₅(PO₄)₃Cl:Eu²⁺.

22. The white light emitting device according to claim 16, wherein said phosphor material blend is one of a conformal coating and disposed on top of said at least one LED chips.

23. The white light emitting device according to claim 16, wherein said phosphor material blend is at least one of coated on the top surface, the bottom surface, and interspersed within said optical element.

24. The white light emitting device according to claim 16, wherein the spectral weight of the red and blue components of the white radiation is at least 50%.

25. The white light emitting device according to claim 16, wherein the white light achieves a CCT of between about 2,500K and 10,000K.

26. The white light emitting device according to claim 16, wherein the red and blue radiation comprising the white light is specifically tailored for plant growth and the white light is suitable for workers.
